(19) United States
(12) Patent Application Publication
(10) Pub. No.: US 2025/0044379 A1
(43) Pub. Date: Feb. 6, 2025

(54) A SYSTEM AND METHOD OF MEASURING ELECTRIC AND/OR MAGNETIC FIELD OF AN OBJECT

(71) Applicant: Argeo Robotics AS, Hvalstad (NO)

(72) Inventors: Johan Mattsson, Trångsund (SE); Thorbjørn Rekdal, Høvik (NO); Trond E. Figenschou Crantz, Hvalstad (NO)

(21) Appl. No.: 18/717,953

(22) PCT Filed: Dec. 9, 2022
(86) PCT No.: PCT/NO2022/050304

§ 371 Date: Jun. 7, 2024

(30) Foreign Application Priority Data
Dec. 10, 2021 (NO) 20211488

(51) Int. Cl. G01R 33/022; B63G 8/00; G01R 33/00; G01R 33/02; G01V 3/15

(52) U.S. Cl. CPC G01R 33/022; G01R 33/0005; G01R 33/0206; G01V 3/15; B63G 8/001

(57) ABSTRACT

The disclosure relates to a system for measuring electric and/or magnetic field of an object, the system comprising: an underwater vehicle comprising: a plurality of links (2a-2d) that are connected to one another by joint modules for generating a flexural motion of the underwater vehicle: wherein the flexural motion devices enable movement of the underwater vehicle and control of the orientation and/or location of the underwater vehicle, wherein the plurality of the links define a hull having a first end (4a) and a second end (4b): a sensor arrangement comprises: a first electrode (6a) mounted on the first end (4a) of the hull: a second electrode (6b) mounted on the second end (4b) of the hull: the first and the second electrode configured to measure electric field of an object, the electric field data sampled with sampling frequencies between 1 and 300 Hz; and/or a first single, 2-, or 3-axes magnetometers (7a) mounted inside the first end (4a) of the underwater vehicle: a second single, 2-, or 3-axes magnetometers (7b) mounted inside the second end (4b) of the underwater vehicle: the single, 2-, or 3-axes magnetometers configured to measure a magnetic field of the object, wherein distance and relative position between the first end of the hull and the second end of the hull is adjustable to enable measuring electric and/or magnetic field in one or more planes/directions. The disclosure further relates to a method of measuring electric and/or magnetic field of an object with an underwater vehicle.

### TECHNICAL FIELD

The present disclosure relates to a system for measuring electric and/or magnetic field of an object and a method of measuring electric and/or magnetic field of an object with an underwater vehicle. More specifically, the disclosure relates to a system for measuring electric and/or magnetic field of an object and a method of measuring electric and/or magnetic field of an object with an underwater vehicle as defined in the introductory parts of claim 1 and claim 5.

### BACKGROUND ART

Maintenance of the infrastructure in a wind farm area, Oil & Gas installation and other similar subsea areas with underwater powerline cables, pipelines, and steel constructions, is important. In a lifecycle perspective, yearly inspections need to be carried out to assure sufficient quality of these vital parts. Traditionally, underwater inspections such as cable and pipeline tracking as well as investigation of cathodic protection systems on steel constructions are carried out with Remotely Operated Vehicles (ROVs). This is tedious, costly, and environmentally unfriendly due to the amount of CO2 emissions from surface vessels during long operations.

To make underwater installation inspection more efficient in terms of duration, cost and to be more environmentally friendly, the use of underwater vehicles equipped with a variety of sensors can be used. Underwater vehicles enable large scanning surveys to be performed in a fast and cost-efficient way. The underwater vehicle can autonomously inspect and track pipelines and cables over large distances. It is also capable of adaptive steering during the tracking. An underwater vehicle can also be configured to scan for Unexploded Ordnance (UXO) over large areas. A recently developed underwater vehicle suitable for various underwater inspections is described in WO 2016/120071 A1. The invention is an underwater robot that can keep a position and that has flexible joints which enables the vehicle to maneuver in different shapes and move close into objects with low risk of damaging the object or the vehicle.

In most of the underwater inspection operations, electromagnetic sensors are used. Magnetic fields sensors and electrode sensors are utilized in a broad range of marine applications to measure the magnetic and electric fields, respectively. For example, measurements of the electric potential field from a cathodic protection system on steel constructions utilizes electrode sensors, M. Galicia, H. Castaneda, Inspection technologies and tools used to determine the effectiveness of cathodic protection for subsea pipelines in the Gulf of Mexico-A review, NACE Corrosion Conference & Expo, 2009 and Gro Østensen

Lunderwater vehiclestad, Harald Osvoll, Jens Christofer Werenskiold, Lars Helgesen, Field Gradient Survey of Offshore Pipeline Bundles affected by Trawling, 2016.

Another application where passive electromagnetic measurements are carried out is tracking of buried powerlines and detection of UXOs. Another passive electromagnetic technology related to pipelines or underwater metal constructions in general is magnetic tomography. A device for magnetographic identification and magnetographic analysis of mechanical flaws is disclosed and described in the patent U.S. Pat. No. 8,949,042 B1.

In addition to passive electromagnetic measurements, Controlled Source Electromagnetic (CSEM) technology in underwater environments is being developed for detection of buried objects like sea mines and unexploded ordnance (UXO). A CSEM method for detecting and locating buried metal objects was developed in year 2000 at the Swedish Defense Research Agency (FOI). The method consisted in a horizontal electric dipole source in combination with a vertical electrode receiver pair in the middle of the source. See Johan Mattsson and Peter Sigray, Electromagnetic Sea-Mine Detection, FOA-R-00-01547-409-SE, ISSN 1104-9154, 2000 and Lennart Crona, Tim Fristedt, Johan Mattsson and Peter Sigray, Sea-trials with active EM for sea-mine detection, FOA-R--00-01757-313-SE, ISSN 1104-9154, 2000for a description and proof of concept of this technology.

### SUMMARY

According to a first aspect there is provided a system for measuring electric and/or magnetic field of an object, the system comprising: an underwater vehicle comprising: a plurality of links that are connected to one another by joint modulesthruste for generating a flexural motion of the underwater vehicle; wherein the flexural motion devices enable movement of the underwater vehicle and control of the orientation and/or location of the underwater vehicle, wherein the plurality of the links define a hull having a first end and a second end; a sensor arrangement comprises: a first electrode mounted on the first end of the hull; a second electrode mounted on the second end of the hull; the first and the second electrode configured to measure electric field of an object, the electric field data sampled with sampling frequencies between 1 and 300 Hz; and/or a first single, 2-, or 3-axes magnetometers mounted inside the first end of the underwater vehicle; a second single, 2-, or 3-axes magnetometers mounted inside the second end of the underwater vehicle; the single, 2-, or 3-axes magnetometers configured to measure a magnetic field of the object, wherein distance and relative position between the first end of the hull and the second end of the hull is adjustable to enable measuring electric and/or magnetic field in one or more planes/directions.

According to some embodiments, the arrangement further comprises: a first gradiometer mounted inside the underwater vehicle; a second gradiometer mounted inside the underwater vehicle and separated a distance from the first gradiometer; the first and the second gradiometers configured to measure gradients of the magnetic field of the object.

According to some embodiments, the sensor arrangement further comprises a processing unit and an acquisition electronics unit located inside the underwater vehicle, the acquisition electronics unit connected to the sensors and configured to receive data from the sensors.

According to some embodiments, the processing unit is configured to receive data from the acquisition electronics unit.

According to a second aspect there is provided a method of measuring electric and/or magnetic field of an object with an underwater vehicle comprising: a plurality of links that are connected to one another by joint modules for generating a flexural motion of the underwater vehicle; wherein the flexural motion devices enable movement of the underwater vehicle and controlling of the orientation and/or location of the underwater vehicle, wherein the plurality of the links defining a hull having a first end and a second end; a sensor arrangement, comprising: a first electrode mounted at the first end of the hull; a second electrode mounted at the second end of the hull; and/or a first and a second single, 2-, or 3-axes magnetometers mounted inside the second end; the method comprising the steps of: measuring electric field data and/or magnetic field from an object with the first and the second electrode and/or the first and the second single, 2-, or 3-axes magnetometers while moving the underwater vehicle sideways along object; using the measured electric field data and/or magnetic field differences in the first and the second electrode and/or in the first and second single, 2-, or 3-axes magnetometers to determining an estimate of a position of the object in relation to the underwater vehicle.

According to some embodiments, the sensor arrangement further the method comprises: a first gradiometer mounted inside the underwater vehicle; a second gradiometer mounted inside the underwater vehicle and separated a distance from the first gradiometer; the first and the second gradiometers configured to measuring gradients of the magnetic field of the object.

According to some embodiments, the method further the method comprises steps of: measuring gradient of the magnetic field data from the object with the first and the second gradiometers while moving the underwater vehicle sideways along the object; using the measured electric field data and the measured gradient of the magnetic field to determining an estimate of a position of the object in relation to the underwater vehicle.

According to some embodiments, the method further the method comprises steps of: measuring gradient of the magnetic field data from the object with the first and the second gradiometers while moving the underwater vehicle perpendicular to its longitudinal form along object; using the measured electric field data and the measured gradient of the magnetic field and the measured magnetic field to determining an estimate of a position of the object in relation to the underwater vehicle.

According to some embodiments, the method further the method comprises a processor which is configured using measurements from the electrodes, magnetometers and the gradiometers to creating a conductivity structure of the object.

According to some embodiments, the processor is further configured to steering the underwater vehicle along the object.

Effects and features of the second aspect are to a large extent analogous to those described above in connection with the first aspect. Embodiments mentioned in relation to the first aspect are largely compatible with the second aspect.

The present disclosure will become apparent from the detailed description given below. The detailed description and specific examples disclose preferred embodiments of the disclosure by way of illustration only. Those skilled in the art understand from guidance in the detailed description that changes and modifications may be made within the scope of the disclosure.

Hence, it is to be understood that the herein disclosed disclosure is not limited to the particular component parts of the device described or steps of the methods described since such device and method may vary. It is also to be understood that the terminology used herein is for purpose of describing particular embodiments only, and is not intended to be limiting. It should be noted that, as used in the specification and the appended claim, the articles “a”, “an”, “the”, and “said” are intended to mean that there are one or more of the elements unless the context explicitly dictates otherwise. Thus, for example, reference to “a unit” or “the unit” may include several devices, and the like. Furthermore, the words “comprising”, “including”, “containing” and similar wordings does not exclude other elements or steps.

### BRIEF DESCRIPTIONS OF THE DRAWINGS

The above objects, as well as additional objects, features and advantages of the present disclosure will be more fully appreciated by reference to the following illustrative and non-limiting detailed description of example embodiments of the present disclosure, when taken in conjunction with the accompanying drawings.

FIG. 1 shows two different views of a flexible underwater vehicle.

FIGS. 2a-2c show illustration of the three different applications of the present invention.

FIGS. 2d-2h show illustration of 3-dimension and rotational movement of the underwater vehicle.

FIG. 3A cross section of the geometry in the modelling of tracking of a buried cable.

FIGS. 4 and 5 show resulting magnetic y-and z-components of the modelled data.

FIG. 6 shows example of buried cable tracking using the magnetic field data.

FIG. 7 shows measurements in the electric potential field from a cathodic measurement system.

FIG. 8 shows an example of the underwater vehicle being maneuvering into a complex underwater structure.

### DETAILED DESCRIPTION

In the following description of embodiments, reference will be made to the drawings, in which like reference numerals denote the same or corresponding elements. It should be noted that, unless otherwise stated, different features or elements may be combined with each other whether or not they have been described together as part of the same embodiment below. The combination of features or elements in the exemplary embodiments are done in order to facilitate understanding of the invention rather than limit its scope to a limited set of embodiments, and to the extent that alternative elements with substantially the same functionality are shown in respective embodiments, they are intended to be interchangeable, but for the sake of brevity, no attempt has been made to disclose a complete description of all possible permutations of features.

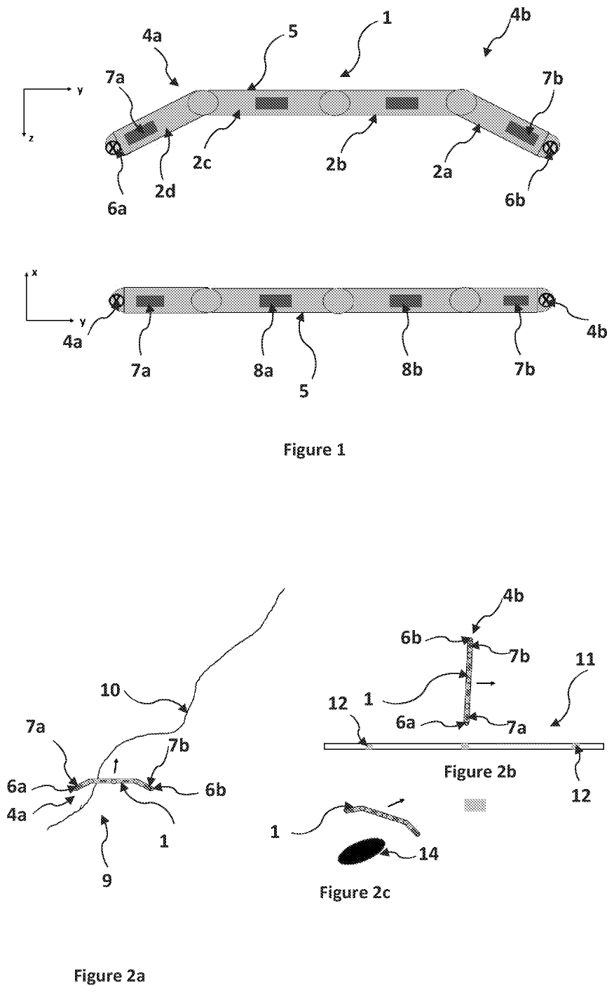

FIG. 1 shows two different views of a flexible underwater vehicle, so called snake robot comprising plurality of links 2a-2d, the plurality of the links defines a hull having a first end 4a and a second end 4b, fins and thruster modules, which are located at various points along the length of the underwater vehicle, the fins and thruster modules enable movement of the underwater robot and control of the orientation and/or location of the tool. The underwater vehicle is equipped with a sensor arrangement comprising at least two electrodes 6a, 6b, each electrode mounted on one end of the hull, the electrodes 6a,6b configured to measure electric field, first and second single, 2-, or 3-axes magnetometers 7a, 7b mounted inside the hull of the underwater vehicle, the magnetometers 7a,7b configured to measure the magnetic field, first and second gradiometers 8a,8b mounted inside the hull of the underwater vehicle, the gradiometers configured to measure gradients of the magnetic field.

The electrodes 6a, 6b are connected through electric wires to an acquisition electronics unit located inside the underwater vehicle. Each of the electrodes constitutes one channel in the measurement system and can be combined arbitrary to get the electric potential difference between any of the electrodes on the underwater vehicle. The electric potential data is sampled in a range between 1-300 Hz. The actual sample rate depends on the specific application. The acquisition electronics unit controls the sampling of the data, digitize the data, and process the data for usage on a main processing unit. Each of the sensor types (magnetometer, gradiometer, electrodes) have their own acquisition electronic unit.

The acquisition electronics unit is adapted to pre-process the data. The pre-processed data is transmitted to a main processing unit where further processing is performed. For example, the magnetic and gradient magnetic data acquired with the sensors can be used together in an inversion algorithm for localization and/or tracking of a partly buried object, fully buried object or/and an object that is resting on the seafloor, such as powerline cables, pipelines, steel constructions, undetected UXOs, etc.

Generally, the sensors of the underwater vehicle are controlled and communicated with through the main processing unit. This main processing unit holds the processing algorithms for each of the applications where data from the electromagnetic sensors are used. The main processing unit receives data from each of the acquisition electronics unit. The main processing unit may be located inside the underwater vehicle or alternatively at a remote location. The main processing unit is adapted to use the measurements from the electrodes, magnetometers and the gradiometers to create a conductivity structure of an object and to steer the underwater vehicle along the object.

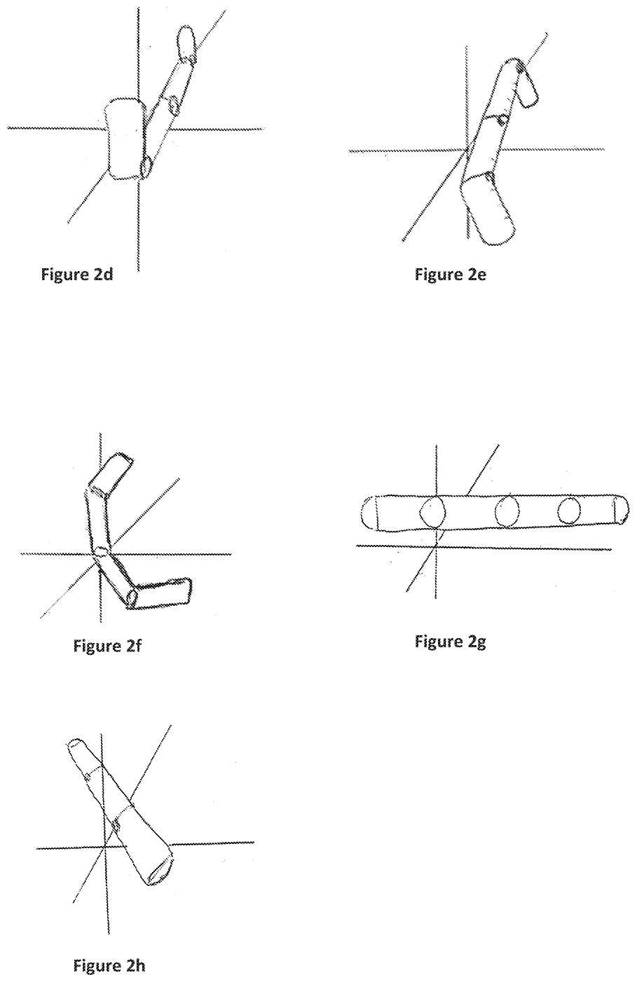

FIG. 2 shows an illustration of three different applications of the present invention. The first one a) shows how the flexible underwater vehicle 1 is moving perpendicular to its longitudinal form when tracking a buried or partly buried object 10, such as powerline cable. The fact that it is moving perpendicular to its longitudinal form is a huge advantage for accurate positioning of the cable. In this configuration, the horizontal cross distance between the magnetometers and electrodes at the ends of the underwater vehicle enables electromagnetic data for unique and accurate estimation of the cable position through data inversion. The outer parts of the underwater vehicle can also be rotated which makes it possible to adjust the crossline separation between the outer sensors. When the underwater vehicle is moving perpendicular to its longitudinal form along the buried object, it will have its first and second ends 4a, 4b almost perpendicular to the buried object 10. With the sensors (electrodes, magnetometers and gradiometer) at each end of the underwater vehicle, the horizontal distance between the sensors is perpendicular to the buried object which results in increased accuracy of the buried object estimation. This makes it possible to determine which side of the underwater vehicle the buried object is positioned. This would not be easy if the underwater vehicle was moving in its length direction. In FIG. 2a, it can be observed that the first electrode 4a and the first 3 axes magnetometers are on opposite side of the buried object compared to the second electrode 4b and the second single, 2-, or 3-axes magnetometers.

The second application of the invention is measurements of a cathodic protection system as shown in FIG. 2b. The underwater vehicle 1 is moving perpendicular to its longitudinal form, but is standing still while measuring the electric potential difference between the first 4a and the second 4b electrodes close to each sacrificial anode 12. The distance and position of the object in relation to the underwater vehicle can be determined from data acquired with other sensors. From FIG. 2b, it can be observed that the sensors 6a, 7a are closest to the object. The most optimal potential difference measurement is obtained radially out from the structure 13 and the anodes 12.

The third application of the invention is shown in FIG. 2c. In this case, a buried unexploded ordnance (UXO) 14 is detected and localized by using the magnetic and gradient magnetic fields from its magnetization. The magnetic fields are preferably used in a detection algorithm and then in an inversion algorithm for the localization. It is beneficial to move the underwater vehicle 1 perpendicular to its longitudinal form when tracking the UXO 14, because it gives a good horizontal cross separation of the outer sensors to get a more accurate detection and localization.

The sensor arrangement system for measuring both the electric and magnetic fields is implemented on the underwater vehicle where the underwater vehicle has the property that its main body as opposite to arms can change shape and extension, and that the underwater vehicle can standstill and move in any direction in the water column.

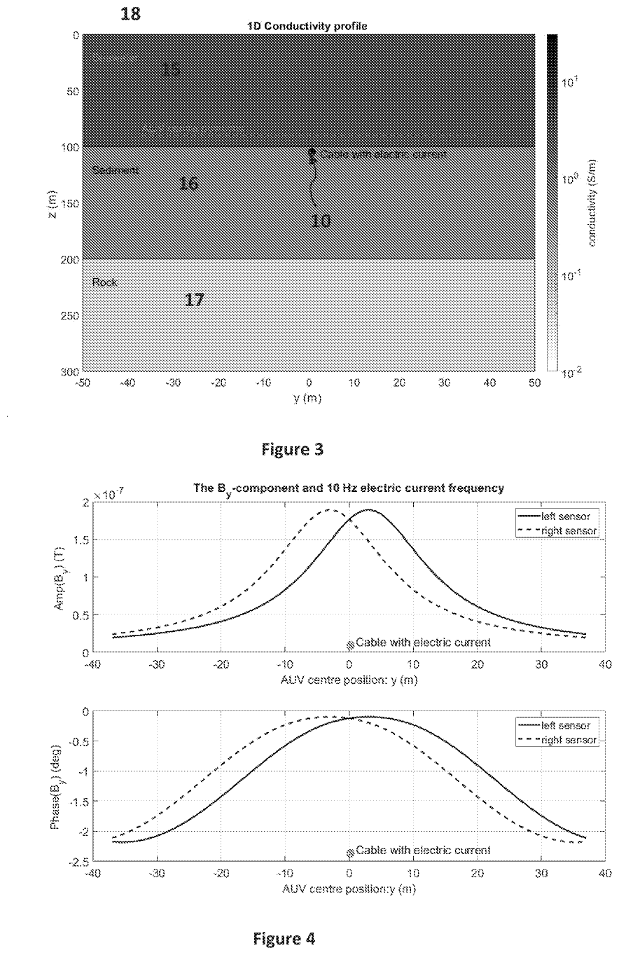

A modelling example is conducted on the two applications illustrated in FIGS. 2a and 2b. The modelling is numerically performed with a simple 1D conductivity environment as shown in FIG. 3. This environment consists of a 100 m thick seawater layer 15 of 3 S/m conductivity. Below the seafloor follows a 100-m thick sediment layer 16 of conductivity of 0.5 S/m. A semi-infinite rock layer 17 of 0.05 S/m underlays both layers 15 and 16. In this case, the air is also represented as the uppermost semi-infinite layer 18 but with zero conductivity. In the modelling case for FIG. 2a, a cable with an electric current of 20 A and frequency 10 Hz is buried 1 m below the seafloor as can be seen in FIG. 3. In the modelling for application 2b, the buried cable is replaced with a pipeline on the seafloor surface. Sacrificial anodes 12 are attached to the pipeline 11 and a simulated electric potential field is modelled.

Starting with the results in application 2a), the magnetic field is computed at two three-axes magnetometers separated by 6 m, i.e., the magnetometers are located at the ends of the underwater vehicle as shown in FIG. 1. The underwater vehicle is placed with its centre point at positions along the white dotted line in FIG. 3. The resulting magnetic y-and z-components are shown in FIGS. 4 and 5, respectively.

In FIGS. 4 and 5, the solid lines show the magnetic field three meters to the left of the underwater vehicle centre position whereas the dotted lines show the resulting field three meters to the right. The magnitudes of the field components are plotted in the upper panels of the figures. The corresponding phases are plotted in the lower panels.

In this specific measurement configuration, the cable in the x-direction, the x-component of the magnetic field is zero. Hence, only the y-and z-components are shown. It can be seen in both FIGS. 4 and 5 that there is a large response in both amplitude and phase. In fact, the response amplitudes are much higher than the expected noise in the system. In this modelling, the expected noise level is about 0.3 nT, which is about 100-1000 times lower than the maximum response amplitudes of the sensitivity. The amplitude and phase differences between the left and right magnetometers are also sufficient to be useful. It can also be observed that sufficient sensitivity to the electric powerline cable is obtained as far out from the cable as 30 m. This means that the total sensitivity width is about 60 m. This would not be possible to achieve without having the underwater vehicle moving perpendicular to its longitudinal form with respect to its body shape. The differences between the sensors would be zero if the underwater vehicle is moving in the direction of its longitudinal form.

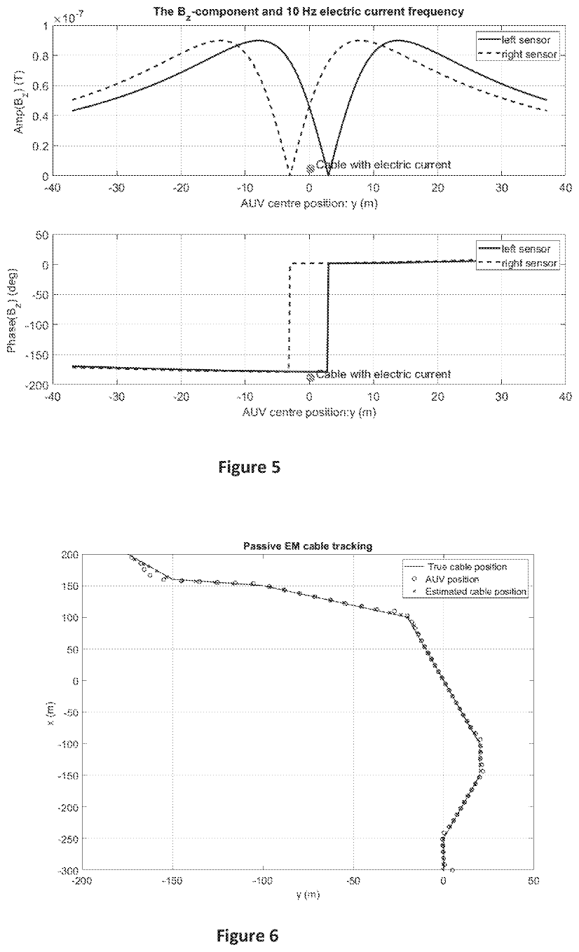

The 6 m separation and the resulting data sensitivity is key for a successful cable tracking as is shown in FIG. 6 below. In the modelling case, the same 1D environmental model is used with the same cable buried 1 m below seafloor but with a horizontal extension according to the true cable position, solid line. The tracking is simulated with modelled data from this cable throughout the tracking. An integration time of 5 s is used which in this simulation case means that the “measured” magnetic field is obtained from modelling data every 5 s. This “measured” data is then feed into an inversion algorithm that is using a simple model of the closest part of the cable to the underwater vehicle and matches the magnetic field from this model with the “measured” data for an estimation of the cable part closest to the underwater vehicle. In a real situation the simulated “measured” data is replaced with real measured data obtained at each 5 s integration time.

The estimated position from one 5 s interval is then used to guide the underwater vehicle closer to the cable in front of the current position towards the next predicted position. The result for this simulation case can be seen with the cross marks (estimated cable positions) and circles (underwater vehicle positions along the cable). The performance is good along the whole cable length. The estimated positions with the crosses are almost spot on the true cable positions and the underwater vehicle is following the estimated positions nicely with a slight delay in steering into the cable when the cable is bending sharply. It should be noted that also the x-component of the magnetic field is used in this simulation since the cable and the underwater vehicle are oriented not only in the x-direction.

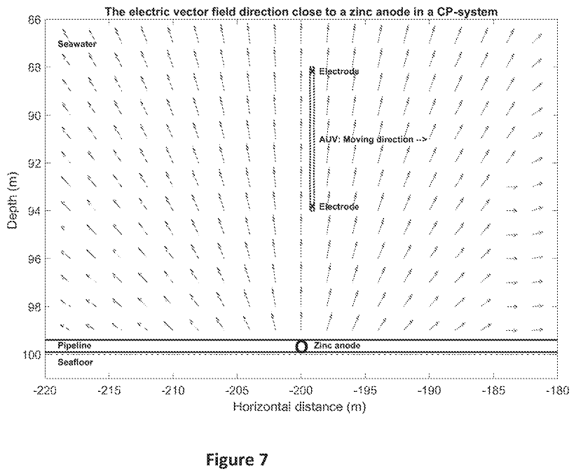

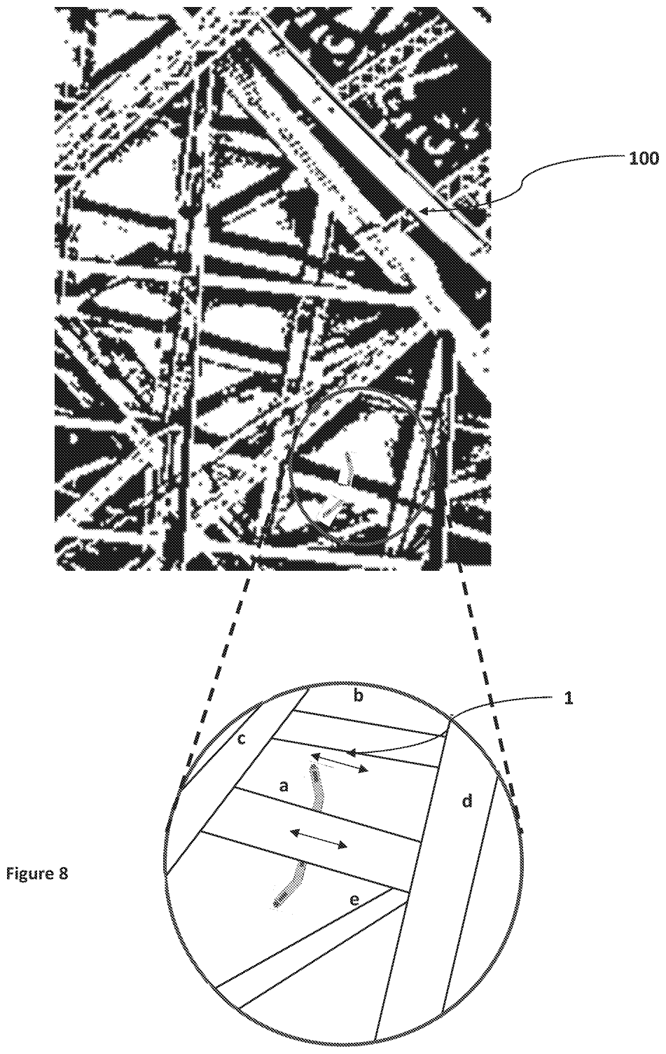

Finally, the modelling result of application b in FIG. 2b is shown in FIG. 7. The interesting feature here is the corresponding electric field orientation visualized with grey arrows. Since the potential difference between two points is the line integral of the electric field between these points, the largest potential difference is obtained in the direction of the electric field, i.e., along the arrows. Hence, the largest potential differences are obtained by measuring radially out from each of the sacrificial anodes along the pipeline.

It is a huge advantage to measure the largest potential differences when estimating the potentials and outgoing electric currents from the sacrificial anodes. A more accurate estimation is obtained which enables more reliable calculations of the absolute electric potential field in the water in the vicinity of the sacrificial anodes.

The first aspect of this disclosure shows a system for measuring electric and/or magnetic field of an object, the system comprising: an underwater vehicle comprising: a plurality of links the first aspecta-2d that are connected to one another by joint modules for generating a flexural motion of the underwater vehicle; wherein the flexural motion devices enable movement of the underwater vehicle and control of the orientation and/or location of the underwater vehicle, wherein the plurality of the links define a hull having a first end 4a and a second end 4b; a sensor arrangement comprises: a first electrode 6a mounted on the first end 4a of the hull; a second electrode 6b mounted on the second end 4b of the hull; the first and the second electrode configured to measure electric field of an object, the electric field data sampled with sampling frequencies between 1 and 300 Hz; and/or a first single, 2-, or 3-axes magnetometers 7a mounted inside the first end 4a of the underwater vehicle; a second single, 2-, or 3-axes magnetometers 7b mounted inside the second end 4b of the underwater vehicle; the single, 2-, or 3-axes magnetometers configured to measure a magnetic field of the object, wherein distance and relative position between the first end 4a of the hull and the second end 4b of the hull is adjustable to enable measuring electric and/or magnetic field in one or more planes/directions.

By providing the underwater vehicle 1 with a plurality of links wherein one or more links can alter its angle relative the neighbor link is specifically advantageous to be able to maneuver into complex underwater structures 100, such as exemplified in FIG. 8. When a structure, for example a complex underwater portion of an oilrig, shall be inspected, it is fair to assume that any portion being protected by a zinc anode of the structure will contribute to the magnetic map wherein the underwater vehicle is maneuvering. The flexibility of the underwater vehicle 1 allow it to position its electrodes 6a, 6b and magnetometers 7a, 7b in the most advantageous position to be able to measure the electric and/or magnetic field of the construction element it intend to measure.

The underwater vehicle 1 further comprises multiple individually controlled thrusters (not shown) enabling a full 360°, 3-dimentional, maneuverability of the underwater vehicle 1 in all directions and rotations.

A further advantage of the underwater vehicle 1 is its ability to move perpendicular to its own longitudinal physical appearance. For example is it advantageous to form a U-form partly around a pipe/leg and move longitudinally along the pipe/leg to measure the electric and/or magnetic field around that specific pipe/leg.

In FIG. 8, the underwater vehicle 1 has maneuvered into a position to measure the field around pipe/leg “a”. By moving right or left the electrodes 6a, 6b and magnetometers 7a, 7b may be held in the most advantageous position relative the pipe/leg “a””, and such be able to ignore disturbing electric and/or magnetic fields form the neighbor pipe/leg “c”, “d”, “e” being arranged close to pipe/leg “a”.

A further advantage of the underwater vehicle 1 is that the electrodes 6A, 6B and magnetometers 7a, 7b may be used in alternate angles when the underwater vehicle is positioned in an electric and/or magnetic field. Thus, the underwater vehicle 1 can by altering its shape position the electrodes and magnetometers in any position relative each other and thereby measure different planes of the electric and/or magnetic field without repositioning or moving through the waters. FIG. 2d to FIG. 2h illustrates how the underwater vehicle 1 is able to alter its position, rotation and “embrace”. The advantage is that the underwater vehicle 1 may detect and produce a complete picture of the electric and/or magnetic field when being still. By being able to alter distance and relative position between the first end 4a of the hull and the second end 4b the underwater vehicle 1 is enable to measure electric and/or magnetic field one or more planes/directions.

The underwater vehicle 1 is provided with a full 3-D maneuverability such that when moving into a complex underwater structure 100 it can “eel” itself into a good position for making measurement of before non-accessible portion of the structure 100.

The arrangement further comprises: a first gradiometer 8a mounted inside the underwater vehicle; a second gradiometer 8b mounted inside the underwater vehicle and separated a distance from the first gradiometer 8a; the first and the second gradiometers configured to measure gradients of the magnetic field of the object.

The sensor arrangement further comprises a processing unit and an acquisition electronics unit located inside the underwater vehicle, the acquisition electronics unit connected to the sensors 6,7,8 and configured to receive data from the sensors.

The processing unit is configured to receive data from the acquisition electronics unit.

The second aspect of this disclosure shows a method of measuring electric and/or magnetic field of an object with an underwater vehicle comprising: a plurality of links the first aspecta-2d that are connected to one another by joint modules for generating a flexural motion of the underwater vehicle; wherein the flexural motion devices enable movement of the underwater vehicle and controlling of the orientation and/or location of the underwater vehicle, wherein the plurality of the links defining a hull having a first end 4a and a second end 4b; a sensor arrangement, comprising: a first electrode 6a mounted at the first end 4a of the hull; a second electrode 6b mounted at the second end 4b of the hull; and/or a first 7a and a second single, 2-, or 3-axes magnetometers 7b mounted inside the second end 4b; the method comprising the steps of: measuring electric field data and/or magnetic field from an object with the first 6a and the second 6b electrode and/or the first 7a and the second single, 2-, or 3-axes magnetometers 7b while moving the underwater vehicle perpendicular to its longitudinal form along object; using the measured electric field data and/or magnetic field differences in the first and the second electrode and/or in the first and second single, 2-, or 3-axes magnetometers to determining an estimate of a position of the object in relation to the underwater vehicle.

The sensor arrangement further the method comprises: a first gradiometer 8amounted inside the underwater vehicle; a second gradiometer 8b mounted inside the underwater vehicle and separated a distance from the first gradiometer 8a; the first and the second gradiometers configured to measuring gradients of the magnetic field of the object.

The method further the method comprises steps of: measuring gradient of the magnetic field data from the object with the first 8a and the second 8b gradiometers while moving the underwater vehicle perpendicular to its longitudinal form along the object; using the measured electric field data and the measured gradient of the magnetic field to determining an estimate of a position of the object in relation to the underwater vehicle.

The method further the method comprises steps of: measuring gradient of the magnetic field data from the object with the first 8a and the second 8b gradiometers while moving the underwater vehicle perpendicular to its longitudinal form along object; using the measured electric field data and the measured gradient of the magnetic field and the measured magnetic field to determining an estimate of a position of the object in relation to the underwater vehicle.

The method further the method comprises a processor which is configured using measurements from the electrodes, magnetometers and the gradiometers to creating a conductivity structure of the object.

The processor is further configured to steering the underwater vehicle along the object.

The person skilled in the art realizes that the present disclosure is not limited to the preferred embodiments described above. The person skilled in the art further realizes that modifications and variations are possible within the scope of the appended claims. Additionally, variations to the disclosed embodiments can be understood and effected by the skilled person in practicing the claimed disclosure, from a study of the drawings, the disclosure, and the appended claims.

1. A system for measuring electric and/or magnetic field of an object, the system comprising an underwater vehicle, wherein the underwater vehicle comprises:
a plurality of links that are connected to one another by joint modules for generating a flexural motion of the underwater vehicle, wherein the-flexural motion devices enable movement of the underwater vehicle and control of the an orientation and/or a location of the underwater vehicle, and wherein the plurality of the links define a hull having a first end and a second end; and
a sensor arrangement comprising:
a first electrode mounted on the first end of the hull, and a second electrode mounted on the second end of the hull, the first and the second electrode configured to measure an electric field of an object, the electric field sampled with sampling frequencies between 1 and 300 Hz; and/or
a first single-, 2-, or 3-axes magnetometers mounted inside the first end of the hull; and a second single-, 2-, or 3-axes magnetometers mounted inside the second end of the hull, the first or the second single-, 2-, or 3-axes magnetometers configured to measure a magnetic field of the object,
wherein a distance and a relative position between the first end of the hull and the second end of the hull are_adjustable to enable measuring electric and/or magnetic field in one or more planes/directions.

2. The system according to claim 1, wherein the sensor arrangement further comprises:
a first gradiometer mounted inside the underwater vehicle;
a second gradiometer mounted inside the underwater vehicle and separated by a distance from the first gradiometer; the first and the second gradiometers configured to measure gradients of the magnetic field of the object.

3. The system according to claim 1, wherein the sensor arrangement further comprises a processing unit and an acquisition electronics unit located inside the underwater vehicle, the acquisition electronics unit connected to the sensor arrangement and configured to receive data from the sensor arrangement.

4. The system according to claim 3, wherein the processing unit is configured to receive data from the acquisition electronics unit.

5. A method of measuring electric and/or magnetic field of an object with an underwater vehicle comprising:
a plurality of links that are connected to one another by joint modules for generating a flexural motion of the underwater vehicle, wherein flexural motion devices enable movement of the underwater vehicle and controlling of an orientation and/or a location of the underwater vehicle, and wherein the plurality of the links define a hull having a first end and a second end; and
a sensor arrangement, comprising:
a first electrode mounted at the first end of the hull, and a second electrode mounted at the second end of the hull; and/or
a first and a second single-, 2-, or 3-axes magnetometers mounted inside the second end,
wherein the method comprises:
measuring electric field data and/or a magnetic field from an object with the first and the second electrode and/or the first and the second single-, 2-, or 3-axes magnetometers while moving the underwater vehicle perpendicular to its longitudinal form along the object;
altering a distance and/or a relative position between the first end of the hull and the second end of the hull for measuring electric and/or magnetic field in one or more planes/directions and,
using measured electric field data and/or magnetic field differences between the first and the second electrode and/or between the first and second single-, 2-, or 3-axes magnetometers to determine an estimate of a position of the object in relation to the underwater vehicle.

6. The method according to claim 5, wherein the sensor arrangement further comprising: comprises
a first gradiometer mounted inside the underwater vehicle; and
a second gradiometer mounted inside the underwater vehicle and separated by a distance from the first gradiometer, and
wherein the method further comprises
configuring a first and a second gradiometers for measuring gradients of the magnetic field from the object.

7. The method according to claim 6, wherein the method further comprises:
measuring a gradient of the magnetic field from the object with the first and the second gradiometers while moving the underwater vehicle sideways along the object; and
using the measured electric field data and the measured gradient of the magnetic field to determine an estimate of a position of the object in relation to the underwater vehicle.

8. The method according to claim 5, wherein the method further comprises:
measuring a gradient of the magnetic field from the object with a first and a second gradiometers while moving the underwater vehicle perpendicular to its longitudinal form along the object;
using the measured electric field data [[and]], the measured gradient of the magnetic field, and the measured magnetic field to determine an estimate of a position of the object in relation to the underwater vehicle.

9. The method according to claim 5, wherein the underwater vehicle further comprises a processor, and wherein the method further comprises:
configuring the processor using measurements from the first and second electrode, the first and second single-, 2-, or 3-axes magnetometer, and a first and a second gradiometers for creating a conductivity structure of the object.

10. The method according to claim 9, further comprising configuring the processor for steering the underwater vehicle along the object.
